(19) United States
(12) Patent Application Publication
(10) Pub. No.: US 2026/0255971 A1
(43) Pub. Date: Aug. 27, 2026

(54) MULTI-MATERIAL COLD PLATE

(71) Applicant: MELLANOX TECHNOLOGIES, LTD., Yokneam (IL)

(72) Inventors: John Franz, Tomball, TX (US); Tahir Cader, Spokane Valley, WA (US); Elad Mentovich, Tel Aviv (IL)

(21) Appl. No.: 19/065,612

(22) Filed: Feb. 27, 2025

(51) Int. Cl. H01L 23/433; H01L 25/18; H10B 80/00; H10D 80/30

(52) U.S. Cl. CPC H10W 40/772; H10W 90/00; H10B 80/00; H10D 80/30

(57) ABSTRACT

Systems are disclosed that support improved cooling of processing units and other computing components in a datacenter or elsewhere. An example of such a system may include a silicon package and a cold plate in thermal contact with the silicon package, where the cold plate has a first portion formed of a first material with a first set of thermal properties and a second portion formed of a second material with second set of thermal properties that is different than the first set of thermal properties.

### FIELD OF THE DISCLOSURE

Embodiments of the present disclosure relate generally to thermal solutions for computing hardware, and more specifically to cooling components used in a datacenter.

### BACKGROUND

Datacenter switch systems and associated modules may include connections between other switch systems, servers, racks, and devices. Such connections may be made using cables, transceivers, cage receptacles, and connector assemblies, which may include a shell or housing configured to protect these connections from damage.

As datacenters continue to operate at higher speeds (e.g., 100 Gb and beyond), the thermal demands on the components in the datacenters increase as well. Heat generation in datacenters occurs primarily due to the electricity used by servers, storage devices, and other hardware components, where nearly all the consumed energy is converted into heat as a byproduct of processing data, essentially meaning that for every watt of electricity used, a watt of heat is produced. The heat requires active and continuous management; otherwise, components of the datacenter may fail under extreme thermal loads. For instance, both cage receptacles and processing units can generate heat during operation, which can result in the failure of those cage receptacles and processing units as well as the failure of system components connected thereto.

### GENERAL DESCRIPTION

Embodiments of the present disclosure aim to address at least some issues associated with thermal loads in a datacenter, and more specifically with thermal loads generated by processing units. As graphics processing unit (GPU) packages increase in size and power, so does the silicon warpage of the package. The GPU package warpage also changes with operating temperature—the package is most warped at room temperature and least warped at operating temperature. The difference between the flattest and most warped states can be several hundred microns. Copper is the most common material used for cold plates due to manufacturing, fluid compatibility and thermal performance. One of the challenges with using copper is its large thermal expansion compared to the silicon package. Copper expands approximately five times more than silicon: the CTE of Copper 16-16.7 ppm, while that of silicon is 3-5 ppm (https://www.engineeringtoolbox.com/linear-expansion-coefficients-d_95.html).

The continued use of copper in cold plates used with larger and higher-power GPUs results in increased stress on the thermal bonding material and silicon package that can lead to cracking and damage, impacting thermal performance or even causing device failure. Using silicon materials instead of copper may solve thermal expansion problems but other issues arise, such as thermal performance and manufacturing challenges. Therefore, there is a need for creating a thermal solution with a combination of materials that can more closely match the coefficient of thermal expansion of the GPU/central processing unit (CPU) silicon package while simultaneously providing thermal efficiency and optimization of manufacturing processes and structural requirements.

Embodiments of the present disclosure solve the problems inherent in the use of different materials in a cold plate and thus enable such use and, as a result, improved thermal performance. More specifically, embodiments of the present disclosure overcome the flatness and thermal expansion challenges of the silicon of the GPU/CPU. All previous solutions use single materials for the micro channel solutions regardless of the manufacturing process (machined, 3D printed, forged, etc). Additionally, current solutions are stiff and unmoving, and are not designed to flex or shift with changing thermal expansion of the part, which can lead to thermal interface pump out, voids, cracks and ultimate thermal failure.

The flexible bellow zones connect different materials on the micro channel component that directly attaches to the GPU. The bellows sections allow two distinct benefits. First, they allow new manufacturing processes to be used and be successful. 3D printing often requires a sintering process where the parts shrink. Attempting to 3D print different materials at the same time is nearly impossible due to the different shrinking ratios during sintering. The bellows transitions between materials allows the shrink rates to not cause warping or part damage. The second benefit is when the micro channel cold plate is attached to the GPU in application. The silicon is not flat and changes dimensions at different temperatures. The size changes constantly over the use of the product with constant heat and cooling cycles. The bellows provides optimum mounting to the non-flat part and then provides movement/flexing as the silicon changes shape. All previous solutions use single materials for the micro channel solutions regardless of the manufacturing process (machined, 3D printed, forged, etc). The second difference is current solutions are stiff and unmoving. They don't flex or shift with changing thermal expansion of the part which can lead to thermal interface pump out, voids, cracks and ultimate thermal failure.

Specifically, and without limitation, embodiments of the present disclosure provide systems that incorporate a cold plate made of different materials and connected with flexible joints to accommodate different rates of thermal expansion resulting from different thermal loads produced by different datacenter components (e.g., graphics processing units (GPUs) and central processing units (CPUs), low-power memory devices). Joining different materials is challenging given the complexity of the thermal expansion rates. However, including flexible transition sections provides key benefits once the system is mounted to the silicon package such that each material can move in XYZ as a function of package warping or expansion from temperature changes. These benefits include reduced stress on the thermal interface and improved reliability of the assembly.

A system according to embodiments of the present disclosure may have a silicon package and a cold plate in contact with the silicon package. The cold plate may include a first portion formed of first material, and a second portion formed of a second material. Either or both of the first portion and the second portion may comprise microchannels positioned therein through which heat transfer fluid may flow. In some embodiments, the microchannels may be defined by micro-fins that facilitate heat dissipation from the first portion and/or the second portion.

The materials from which the first and second portions of the cold plate are formed may have different sets of thermal properties or characteristics, including different coefficients of thermal expansion (CTEs). The first portion may be positioned directly on top of or otherwise in contact with a first datacenter component (e.g. a GPU or CPU) that produces a first thermal load when operating, and the second portion may be positioned directly on top of or otherwise in contact with a second datacenter component (e.g., a low-power memory device, such as a DRAM or an HBM silicon area) that produces a second thermal load when operating. The first thermal load may be greater than the second thermal load, or vice versa.

The first and second materials may be selected based on the actual or predicted first thermal load and second thermal load, respectively. The first or the second material may be selected to have a CTE that matches a CTE of a silicon die, to minimize differences in expansion and contraction between the first or second portion, respectively, and the datacenter component with which the first or second portion is in contact. The other material (i.e., the second or the first material, respectively) may be a thermally conductive material (such as copper, silver, diamond, graphite, boron nitride, and/or any other thermally conductive material) and may have a CTE greater than the CTE of the first material.

In some examples, the first portion and the second portion may be substantially co-planar, and/or may be joined by a flexible border that allows each of the first portion and the second portion to expand, contract, warp, and otherwise deform and/or move independently of each other. One or both of the first portion and the second portion may be bonded to the flexible border (e, g, by their respective edges), for example using a brazing or a bonding diffusion technique. If the two parts were bonded rigidly together one or both would either warp or crack. These thermal expansion and contraction rates are even more critical if manufacturing the device using a 3D printing process that requires sintering of the materials. The flexible border may be a flexible bellows linkage providing optimum mounting to the non-flat part and then providing movement/flexing as the silicon changes shape. The system may include a stiffener frame (e.g. ring) for mounting the assembly to the package substrate as well as connecting the assembly to the remaining cold plate components and supporting the first and second portion either directly or indirectly. The stiffener frame may surround the first portion and/or the second portion, and may be connected to the first portion and/or the second portion via a flexible link, such as a flexible bellows linkage.

The present disclosure relates in general to cooling data center components. Datacenters comprise multiple components, including processing units and other chips interconnected using optical, active, and high-powered cables and associated connector assemblies used in conjunction with datacenter switch systems, modules, and other optical and electrical components. In particular, cages, shells, and housings of connector and receptacle assemblies may utilize heat dissipation units and elements that are configured to increase the thermal performance of connector assemblies.

Datacenter switch systems and associated modules may generally include connections between other switch systems, servers, racks, and devices. Such connections may be made using cables, transceivers, cage receptacles, and connector assemblies, which may include a shell or housing configured to protect these connections from damage. Often, these cage receptacles can generate heat during operation, which can result in the failure of system components.

Example aspects of the present disclosure include solutions to help cool one or more components of a datacenter as described herein.

In some embodiments, a system is provided that includes: a silicon package; and a cold plate in thermal contact with the silicon package, wherein the cold plate comprises a first portion formed of a first material and a second portion formed of a second material, wherein the first material comprises a first set of thermal properties and the second material comprises a second set of thermal properties different than the first set.

According to some aspects, the first portion is substantially co-planar with the second portion.

According to some aspects, the first portion is joined to the second portion by a flexible border.

According to some aspects, the flexible border is bonded to at least one of the first portion or the second portion.

According to some aspects, the flexible border is bonded to both the first portion and the second portion.

According to some aspects, the flexible border comprises a flexible bellows linkage.

According to some aspects, at least one of the first portion and the second portion comprises microchannels.

According to some aspects, the first portion comprises a micro-finned structure.

According to some aspects, the silicon package comprises a GPU core, and the micro-finned structure is positioned directly on top of the GPU core.

According to some aspects, the silicon package comprises a GPU core, and the micro-finned structure is positioned in contact with the GPU core.

According to some aspects, the second portion comprises a micro-finned structure.

According to some aspects, the system further includes a memory device, where the micro-finned structure is directly on top of the memory device. The memory device may include a low-power memory device. For example, the memory device may include a DRAM or HBM silicon area.

According to some aspects, the first portion comprises a silicon-based material.

According to some aspects, the first portion has a coefficient of thermal expansion substantially similar to a silicon die thermal coefficient of expansion.

According to some aspects, the second portion comprises a conductive material.

According to some aspects, the conductive material is copper.

According to some aspects, the system may further include a stiffener frame. The stiffener frame may surround both the first portion and the second portion of the cold plate. The stiffener frame may include a flexible bellows linkage connected to at least one of the first portion and the second portion.

In at least some embodiments, a system is provided that includes: a silicon package comprising a processor core; and a cold plate in thermal communication with the silicon package, the cold plate comprising: a first portion having a first coefficient of thermal expansion; a second portion having a second coefficient of thermal expansion different than the first coefficient of thermal expansion; and a stiffener frame configured to provide support to both the first portion and the second portion.

According to some aspects, the system further includes a flexible border between the first portion and the second portion. The flexible border may allow each of the first portion and the second portion to expand and contract independently of each other. The flexible border may be bonded to at least one of the first portion and the second portion using a brazing or a bonding diffusion technique.

According to some aspects, a first part of the silicon package is mounted to the first portion and a second part of the silicon package is mounted to the second portion.

According to some aspects, the first part uses a first power level and the second part uses a second power level.

According to some aspects, the first part comprises a memory device and the second part comprises the processor core.

In at least some embodiments, a system is provided that includes: a manifold defining a heat transfer fluid inlet and a heat transfer fluid outlet; and a pedestal, including: a first portion having a first set of thermal characteristics; a second portion having a second set of thermal characteristics different than the first set of thermal characteristics, the second portion connected to the first portion via a flexible link; and a stiffener frame configured to provide support to at least one of the first portion and the second portion; where the manifold is removably secured to the pedestal via the stiffener frame.

According to some aspects, the first portion is in thermal contact with at least one processor core, and the second portion is in thermal contact with at least one memory device.

According to some aspects, the second portion surrounds the first portion, the stiffener frame surrounds the second portion, and the stiffener frame comprises a second flexible link connected to the second portion.

Any aspect in combination with any one or more other aspects.

Any one or more of the features disclosed herein.

Any one or more of the features as substantially disclosed herein.

Any one or more of the features as substantially disclosed herein in combination with any one or more other features as substantially disclosed herein.

Any one of the aspects/features/implementations in combination with any one or more other aspects/features/implementations.

Use of any one or more of the aspects or features as disclosed herein.

It is to be appreciated that any feature described herein can be claimed in combination with any other feature(s) as described herein, regardless of whether the features come from the same described implementation.

The details of one or more aspects of the disclosure are set forth in the accompanying drawings and the description below. Other features, objects, and advantages of the techniques described in this disclosure will be apparent from the description and drawings, and from the claims.

Numerous additional features and advantages of the present disclosure will become apparent to those skilled in the art upon consideration of the implementation descriptions provided hereinbelow.

Additional features and advantages are described herein and will be apparent from the following Description and the figures.

### BRIEF DESCRIPTION OF THE SEVERAL VIEWS OF THE DRAWINGS

Having thus described the disclosure in general terms, reference will now be made to the accompanying drawings, which are not necessarily drawn to scale:

FIG. 1 is a block diagram illustrating an example network architecture according to at least some embodiments of the present disclosure;

FIG. 2 schematically illustrates various components of a network architecture according to at least some embodiments of the present disclosure;

FIG. 3 is a perspective view of a datacenter rack according to at least some embodiments of the present disclosure;

FIG. 4A is a perspective view of a cage receptacle assembly according to at least some embodiments of the present disclosure;

FIGS. 4B-4C illustrate an example cable connector according to at least some embodiments of the present disclosure;

FIG. 5 is a block diagram of a system according to at least some embodiments of the present disclosure;

FIG. 6 is an exploded upper perspective view of a system according to at least some embodiments of the present disclosure;

FIG. 7 is an exploded lower perspective view of the system of FIG. 6;

FIG. 8 is a plan view of the system of FIG. 6;

FIG. 9 is a partial section view of the system of FIG. 6, taken along plan A-A from FIG. 6;

FIG. 10 is a detailed view of the portion of FIG. 9 enclosed within box A;

FIG. 11 is a detailed view of the portion of FIG. 9 enclosed within box B;

FIG. 12 is a block diagram illustrating a computer system according to at least some embodiments of the present disclosure;

FIG. 13 is a block diagram illustrating details of network devices according to at least some embodiments of the present disclosure; and

FIG. 14 is a block diagram illustrating further details of a datacenter and components thereof according to at least some embodiments of the present disclosure.

Like reference numbers and designations in the various drawings may indicate like elements.

### DETAILED DESCRIPTION

The ensuing description provides embodiments only, and is not intended to limit the scope, applicability, or configuration of the claims. Rather, the ensuing description will provide those skilled in the art with an enabling description for implementing the described embodiments. It is understood that various changes may be made in the function and arrangement of elements without departing from the spirit and scope of the appended claims.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

Various aspects of the present disclosure will be described herein with reference to drawings that are schematic illustrations of idealized configurations.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this disclosure.

As used herein, the singular forms “a,” “an,” and “the” are intended to include the plural forms as well, unless the context clearly indicates otherwise. It will be further understood that the terms “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

The present disclosure now will be described more fully hereinafter with reference to the accompanying figures in which some but not all embodiments of the disclosures are shown. Indeed, the present disclosure may be embodied in many different forms and should not be construed as limited to the embodiments set forth herein.

Like numbers refer to like elements throughout. As used herein, terms such as “front,” “rear,” “top,” etc. are used in the examples provided below to describe the position of certain components or portions of components in an installed and operational configuration. As used herein, the term “module” encompasses hardware, software and/or firmware configured to perform one or more particular functions, including but not limited to conversion between electrical and optical signals and transmission of the same. As would be evident to one of ordinary skill in the art in light of the present disclosure, the term “substantially” indicates that the referenced element or associated description is accurate to within applicable engineering tolerances.

Processing stacks according to embodiments of the present disclosure may be connected to one another and to other datacenter components using a pluggable connector such as an octal small form factor pluggable (OSFP); a Quad Small Form-factor Pluggable (QSFP) connector; or any other connector (e.g., Small Form Pluggable (SFP), C-Form-factor Pluggable (CFP), and the like). Moreover, such connections may use any cable (e.g., passive copper cable (PCC), active copper cable (ACC), or the like) or interconnect utilized by datacenter racks and associated switch modules (e.g., an active optical module (AOM), QSFP transceiver module, or the like).

Additionally, processing stacks according to embodiments of the present disclosure may utilize transceiver systems to facilitate communication with other datacenter components, which transceiver systems may comprise, for example, a vertical-cavity surface-emitting laser (VCSEL) as one element thereof. However, embodiments of the present disclosure may be equally applicable for use with any transceiver system and/or element. Similarly, communications between processing stacks according to embodiments of the present disclosure may be facilitated by a switch module configured to receive a cage receptacle assembly to allow signals to pass between a cable connector and the switch module. The present disclosure, however, contemplates that a network interface, a high-capacity adapter, or any other applicable networking interface may equally be used instead or in conjunction with the switch module to receive the cage receptacle and facilitate communications among various datacenter components.

Embodiments of the present disclosure are contemplated to be deployed in a datacenter environment. While embodiments will be described in connection with certain examples of datacenter environments, it should be appreciated that embodiments of the present disclosure are not so limited. Indeed, embodiments of the present disclosure contemplate the ability to deploy bottom-side cooling as disclosed herein in any number of environments including a datacenter environment or any other suitable environment that requires the management of thermal loads generated by computing components.

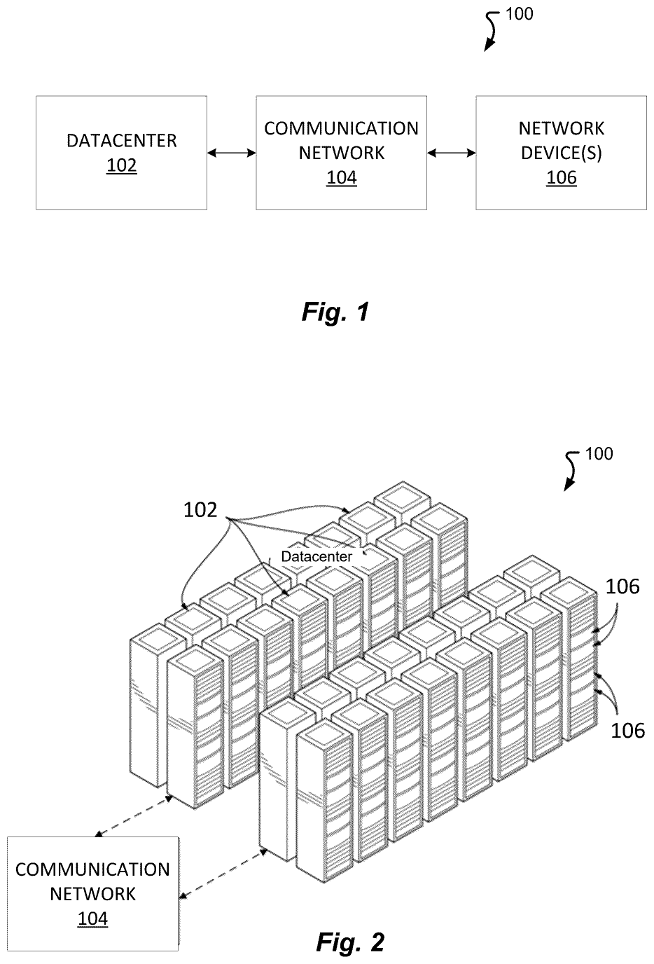

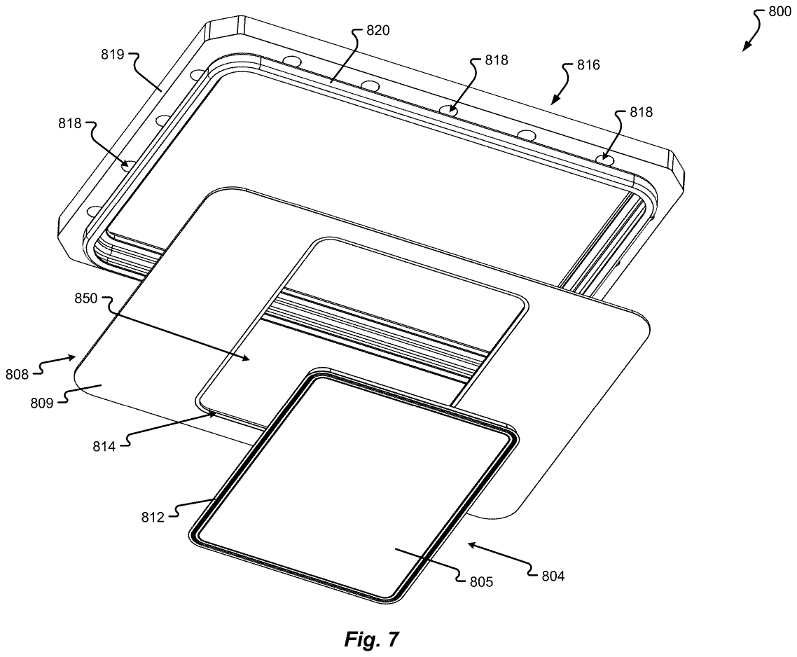

Illustrative datacenter environments and components are shown and will now be described with reference to FIGS. 1 through 14.

Datacenters, high performance computing clusters, and/or the like are often formed of various computing components or networked devices, and communication networks formed of electrical and/or optical devices may be used to enable communication between the networked devices forming these implementations. As shown in FIGS. 1, 2, and 13, for example, a network architecture 100 may include a datacenter 102, a communication network 104, and network device(s) 106. The network architecture 100 may illustrate a general computing architecture within which more specific systems and/or subsystems may function. Although described hereinafter with reference to a network architecture 100 and/or datacenter 102 within which the embodiments of the present disclosure may be implemented, the present disclosure contemplates that the transceiver resiliency devices and techniques described herein may be applicable to any communication implementation without limitation.

For example, the datacenter 102 may be a centralized facility designed to house computing resources and related components. The datacenter 102 may operate to support the infrastructure required for advanced computational tasks, for efficient, secure, and reliable operations. The datacenter 102 may include the building and structural components, including power supplies, cooling systems, fire suppression systems, and physical security measures that are configured to maintain optimal operating conditions and/or protect the equipment from environmental hazards and unauthorized access. An example datacenter 102 may include high-performance servers or compute nodes, often arranged in racks, such as those illustrated in FIG. 2, and connected through high-speed networks as described herein. These servers may include processors (e.g., central processing units (CPUs), graphics processing units (GPUs), data processing units (DPUs) and/or the like), memory (e.g., RAM), and storage solutions (e.g., hard disk drives (HDDs), solid state drives (SSDs), and/or the like. The hardware configuration may be designed for parallel processing and high throughput, catering to the demands of high-performance computing (HPC) applications.

In one example, the processors may include central processing units (CPUs), graphics processing units (GPUs), data processing units (DPUs), quantum processing units (QPUs), a plurality of parallel processing units (PPUs), and application-specific integrated circuits (ASICs). QPUs configured to perform one or more operations associated with a quantum algorithm In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU with which the local qubits are associated.

The datacenter 102 may include high-speed network equipment, such as network switches, routers, firewalls, and/or the like to facilitate fast and secure data transmission within the datacenter 102 (e.g., between the servers or compute nodes) and between external networks. The datacenter 102 may facilitate communication between servers or compute nodes through a network topology that ensures efficient data exchange, minimizes latency, and maximizes bandwidth. The network topology may dictate how various network devices, such as switches and routers, are interconnected for data flow. By implementing an effective network topology, the datacenter 102 may support high-performance computing tasks. Examples of various network topologies may include hierarchical networking topologies such as the fat tree topology, Slim Fly topology, Dragonfly topology, and/or the like. The datacenter 102 may adhere to a networking topology (e.g., a hierarchal networking topology), such as a fat tree topology, a Slim Fly topology, a Dragonfly topology, and/or the like. The datacenter 102 routes traffic amongst the network switches and servers therein, and at least one layer of the topology in the datacenter 102 is coupled to the communication network 104 to allow networking traffic to flow between the datacenter 102 and the network device(s) 106.

The communication network 104 may communicably couple the datacenter 102 with network device(s) 106 and other external devices for data exchange and connectivity. Examples of the communication network 104 may include an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like. The ability of the communication network 104 to incorporate multiple network types and configurations may allow the datacenter 102 to adapt to diverse application needs, from general data communication to specialized HPC tasks. As described herein, the communication network 104 may leverage various optical components to establish communication links (e.g., communicably couple) between components in the architecture 100. As such, the communication network 104 may include various optical devices, transceivers, modules, and/or the like that are configured to generate optical signals (e.g., provide optical transmitter functionality) and/or receive optical signals (e.g., provide optical receiver functionality).

The network device(s) 106 may include a variety of computing devices capable of transmitting and receiving signals over the communication network 104. The network device(s) 106 may range from personal computing devices to complex server configurations. Examples include Personal Computers (PCs), laptops, tablets, smartphones, and servers. The network device(s) 106 may facilitate user interactions with the datacenter 102, allowing for data input, retrieval, and processing from remote locations. In addition to individual computing devices, the network device(s) 106 may also include collections of servers or additional datacenters. For instance, these could be other datacenters similar to or the same as datacenter 102. Such an interconnection may allow for the formation of a distributed computing environment for improved redundancy, load balancing, and disaster recovery capabilities. By linking multiple datacenters, the network architecture 100 may leverage geographically dispersed resources, optimizing performance and ensuring high availability.

As described herein, the datacenter 102 and/or the network device(s) 106 may include storage devices and processing circuitry for executing computing tasks, such as controlling the flow of data internally and over the communication network 104. The processing circuitry may include software, hardware, or a combination thereof. For example, the processing circuitry may include a memory containing executable instructions and a processor (e.g., a microprocessor) that executes these instructions. The memory may correspond to any suitable type of memory device or collection of memory devices configured to store instructions. Non-limiting examples of suitable memory devices include Flash memory, Random Access Memory (RAM), Read Only Memory (ROM), variants thereof, combinations thereof, or similar technologies. In specific embodiments, the memory and processor may be integrated into a common device, such as a microprocessor with integrated memory. Additionally, or alternatively, the processing circuitry may comprise hardware components, such as an application-specific integrated circuit (ASIC). Other non-limiting examples of processing circuitry include Integrated Circuit (IC) chips, CPUs, GPUs, microprocessors, Field Programmable Gate Arrays (FPGAs), collections of logic gates or transistors, resistors, capacitors, inductors, and diodes. Some or all of the processing circuitry may be provided on a Printed Circuit Board (PCB) or a collection of PCBs. It should be appreciated that any appropriate type of electrical component or collection of electrical components may be suitable for inclusion in the processing circuitry.

In addition, although not explicitly shown, the present disclosure contemplates that the datacenter 102 and network device(s) 106 may include one or more communication interfaces for facilitating wired and/or wireless communication between one another and other unillustrated elements of the network architecture 100. These communication interfaces may include a variety of technologies, including but not limited to Ethernet ports, fiber optic connections, Wi-Fi® transceivers, Bluetooth® modules, and cellular communication modules for integration and interoperability among the various components within the network architecture 100.

Furthermore, the present disclosure contemplates that the network architecture 100 may include additional components and functionalities. For example, the network architecture may include, without limitation, additional processing units, specialized accelerators (such as Tensor Processing Units or TPUs), enhanced security modules, and redundant power supplies. The inclusion of these elements may be intended to ensure that the network architecture 100 is robust, scalable, and capable of meeting diverse operational requirements. Any variations, modifications, or adaptations of the described elements that fall within the spirit and scope of the disclosure are considered to be encompassed by the present disclosure. This includes any combinations, sub-combinations, or enhancements of the various described elements to achieve improved performance, reliability, and efficiency in the network architecture 100.

In high-capacity datacenter networks, the communication network 104 may leverage optical transceivers that transmit and receive optical signals over optical fibers or other optical communication mediums to establish connection between devices in the architecture 100.

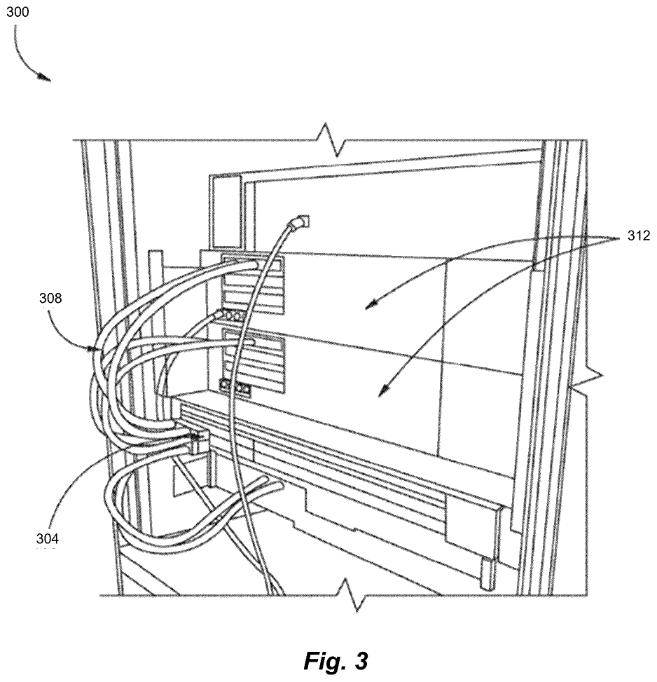

FIG. 3 illustrates an example datacenter rack 300, or cabinet that is designed to house servers, networking devices, modules, and other datacenter 102 computing equipment and used in conjunction with optical cable(s) 308.

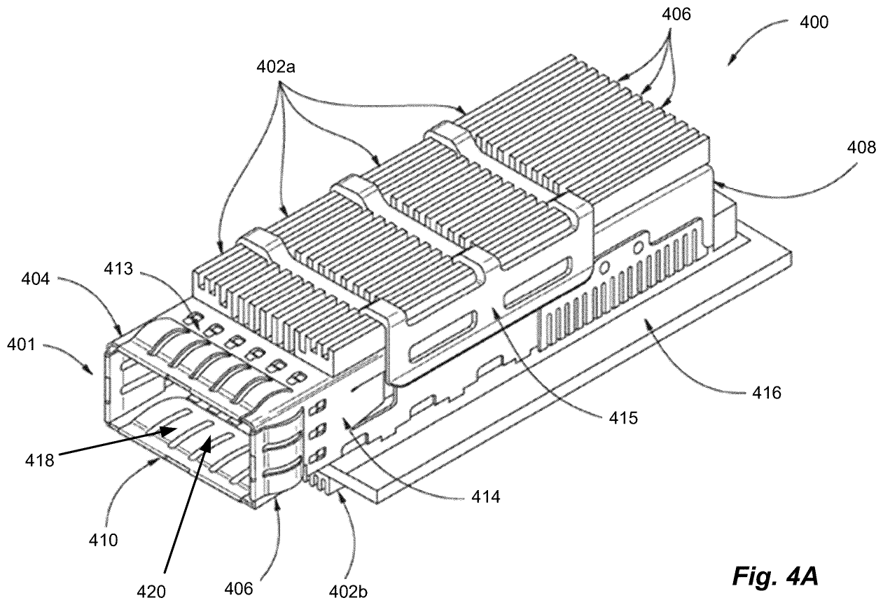

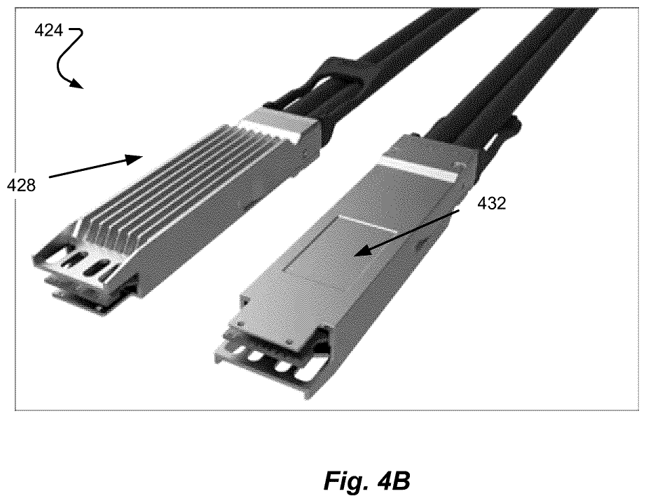

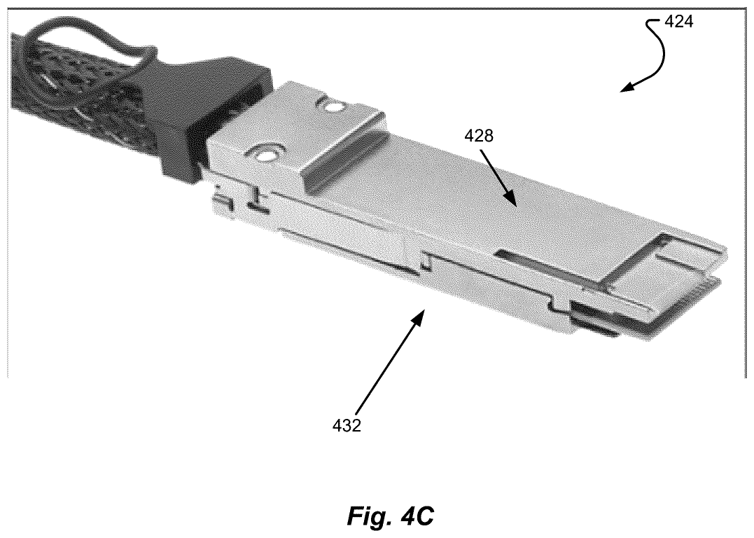

Different types of cable connectors, such as those illustrated in FIGS. 4B and/or 4C, exist for enabling transmission of signals (optical and/or electrical) between switch modules and other equipment in a datacenter. For example, OSFP connectors and cables, as well as other forms of connectors such as QSFP, Small Form Pluggable (SFP), and C-Form-factor Pluggable (CFP) connectors provide high-speed information operations interface interconnects. Regardless of the type of cable connectors, these transceivers may interface a switch system board, such as a motherboard in a switch system, to a fiber optic or copper networking cable, such as by making connections between switch modules 312 as shown in FIG. 3.

With continued reference to FIG. 3, for example, a switch module 312 (or other interconnect module), which may house an application-specific integrated circuit (ASIC) as well as other internal components (not visible), is typically incorporated into a datacenter 102 or 1400 via connections to other switch systems, servers, racks, and network components. A switch module 312 may, for example, interact with other components of the datacenter 102 or 1400 via external optical cables 308 and possible transceiver systems housed in the end of an optical cable 308. These optical cables 308 and transceivers may allow connections between a switch module 312 and the other components of the datacenter 102 or 1400 via cage receptacle assemblies 304.

The switch modules 312 may be configured to be received by a datacenter rack 300 and may be configured to allow for the conversion between optical signals and electrical signals. For example, optical cables 308 may carry optical signals as inputs to the switch module 312. The optical signals may be converted to electrical signals via an opto-electronic transceiver assembly, which may form part of the optical cable 308 in cases in which the optical cable 308 is an Active Optical Cable (AOC), such as a cable that includes an OSFP connector that is received by a port of a switch module 312. In other cases, the optical cable 308 may be passive, and the switch module 312 may include opto-electronic components that convert between optical signals and electrical signals. The electrical signals may then be processed by the switch module 312 and/or routed to other computing devices, such as servers and devices on other racks or at other datacenters via other components and cables (not shown). In addition, electrical signals received from other networking devices (e.g., from other datacenters, racks, etc.) may be processed by the switch module 312 and then converted into corresponding optical signals to be transmitted via the optical cables 308, going the opposite direction.

The transmission of data as electrical signals and the conversion between optical signals and electrical signals (e.g., via an AOC and associated transceiver system or AOM) often results in the generation of heat by the components of the datacenter rack 300. As can be appreciated, higher temperatures associated with such heat emissions can correspond to the increased likelihood of failure of electrical components and/or changes in the electrical and/or optical operating parameters of the components resulting in interference with the corresponding electrical and/or optical signals. Additionally, localization or concentration of higher temperatures in electrical components (e.g., the bottom surface of the AOC, AOM, or pluggable cable connector) can result in a further increase in the likelihood of failure of electrical components located near the area of heat concentration.

Accordingly, embodiments of the disclosure described herein provide a cage receptacle assembly that is configured to provide increased thermal efficiency by allowing the heat dissipation units to be independently adjustable relative to the cage body (e.g., “floating”), so that their spatial position and orientation state is aligned with the position and orientation of the respective top or bottom surfaces of the plugged transceiver to achieve effective heat transfer from the transceiver surfaces to the heat dissipation elements. In embodiments, the contact area between the transceiver and heat dissipation unit(s) is enlarged to allow for more surface area of the transceiver contacting the heat dissipation unit(s) to distribute heat more evenly and/or to more effectively dissipate the heat to the surrounding environment to maintain lower temperatures in the components.

It should further be noted that a cable 308 (and similarly the other active optical cables described herein) and connectors may be designed to comply with any applicable standard, for example Ethernet and InfiniBand standards, such as Ethernet variants 200GBASE-FR4, 400GBASE-FR4, and 100GBASE-LR4 to support four wavelengths. Connections between the cable 308 and the switch module 312 may be facilitated by one or more of a transceiver module and a cage receptacle assembly.

FIG. 4A illustrates one example of a cage receptacle assembly 400 (also referred to herein simply as a cage 400). One or more cage receptacle assemblies 400 may be included, for example, in the substructure 532 of the stack 501. The cage assembly receptacle assembly 400 is shown to include a cage body 401.

The cage body 401 of the cage 400 may be defined by a top cage member 404 that defines a top portion 413 and two side portions 414 that extend between the top portion 413 of the top cage member 404 to a bottom cage member 406. The top cage member 404 may be configured to attach to the bottom cage member 406 to form the cage body 401. The cage body 401 of the cage 400 may be configured to at least partially receive a cable connector 424 (also referred to herein as a connector plug 424) as illustrated in FIG. 4B or 4C (e.g., a QSFP cable and/or connector) such that a top surface 428 of the cable connector 424 is disposed proximate the top cage member 404 and a bottom surface 432 of the cable connector 424 is disposed proximate the bottom cage member 406.

The cage 400 may also define a first end 410 and a second end 408 opposite the first end 410, where the first end 410 is configured to receive a cable connector such as the cable connector 424 illustrated in FIGS. 4B-4C. For example, the first end 410 of the cage 400 may be defined such that at least a portion of the cable connector 424 may be inserted into the cage 400 or otherwise brought into engagement or contact with an inner surface 418 of cage body 401 via the first end 410. The first end 410 may be configured to receive a cable connector 424 of any suitable dimension or of any suitable type (e.g., AOC, Ethernet, Direct Attach Copper, etc.) such that the top cage member 404 is located proximate to the top surface 428 of the cable connector 424 and the bottom cage member 406 is located proximate to the bottom surface 432 of the cable connector 424. As a non-limiting example, the first end 410 may be configured to receive a cable connector 424 corresponding to a QSFP cable connector, such that the QSFP is secured to the cage receptacle assembly 400 by engaging at least a part of the inner surface 418 of the cage body 401 via the first end 410.

The cage body 401 may further define a second end 408 opposite the first end 410, where the second end 408 is configured to be received by a module for enabling signals to pass between the cable connector 424 and a module. The cage 400 may be configured to engage, or be secured to, a module (e.g., switch module 412). The cage receptacle assembly 400 may be configured such that the second end 408 defines at least one extension capable of being received by a datacenter switch module 412 (e.g., male to female connection). As discussed above, the opening 720 defined by the cage body 401 of the cage 400 may be such that a cable connector 424 may extend through the cage body 401 of the cage receptacle assembly 400. Specifically, the cable connector 424 may be configured (e.g., sized and shaped) such that upon engagement of the second end 408 of the cage receptacle assembly 400 with the module, the cable connector 424 may also engage the switch module 412 such that signals may be transmitted between the cable 424 and switch module 412.

By way of a more particular example, a connector 424 may be received by the cage 400 such that at least a portion of the connector 424 is supported and/or surrounded by the cage body 401 of the cage 400. Illustratively, connector 424 (e.g., the end of a cable configured to engage a module and allow electrical communication therethrough) may be positioned such that when the cage 400 engages the module 412, the connector plug 424 engages a corresponding port of the system to allow signals (e.g., electrical signals, optical signals, or the like) to travel between the connector and the module.

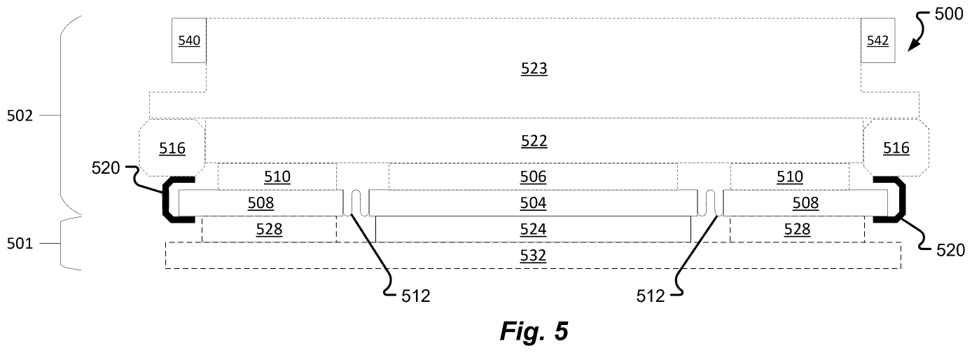

With reference now to FIG. 5, a block diagram of a system 500 will be described in accordance with at least some embodiments of the present disclosure. The system 500 comprises a cold plate 502 mounted directly on top of a stack 501, which is a silicon package and may be, for example, a 2.5D stack. The stack 501 comprises a processing tier 524; one or more memory sections 528; and substructure 532.

The processing tier 524 comprises one or more processing cores or units, such as one or more GPUs, one or more CPUs, and/or one or more of any other processing core or unit. In some embodiments, the system 500 comprises only a single processing tier (e.g., the processing tier 524). In other embodiments, the system 500 may comprise one or more additional processing tiers, which may be the same as or similar to the processing tier 524 and may be positioned at the same vertical level as the processing tier 524 or at one or more different vertical layers relative to the processing tier 524. The processing tier 524 may be configured to execute instructions stored in one or more of the memory sections 528 and/or received via the substructure 532, and may also be configured to generate electrical signals for transmission to one or more of the memory sections 528 and/or to datacenter components external to the system 500 via the substructure 532.

During operation, the processing tier 524 may generate a high thermal load. That thermal load may cause the processing tier 524 to expand, warp, and or otherwise deform relative to the state of the processing tier 524 when it is not in use. Such expansion, warpage, or other deformation may occur in one or multiple planes.

The memory sections 528 comprise one or more memory devices. The memory devices may be or comprise, for example, a low-power memory die such as a High Bandwidth Memory (HBM) stack or a Dynamic Random Access Memory (DRAM) layer. The memory devices may additionally or alternatively be or comprise, for example, a Static Random Access Memory (SRAM) layer, and/or a Magnetoresistive Random Access Memory (MRAM) layer. The memory sections 528 store data, which may in some embodiments include instructions for execution by one or more processors included in the processing tier 524. The data stored in the memory sections 528 may be accessed (e.g., read, written, or both, via the substructure 532) by other components of a datacenter 202 or other computing environment in which the system 500 is used. The data stored in the memory sections 508 may also be accessed by the processing tier 524, whether directly or via an interposer or other device.

During operation, the memory sections 528 may generate a thermal load that is lower than the thermal load generated by the processing tier 524. That thermal load may cause the memory sections 528 to expand, warp, and or otherwise deform relative to the state of the memory sections 528 when it is not in use. Such expansion, warpage, or other deformation may occur in one or multiple planes. Where the memory section 528 generates a lower thermal load than the processing tier 524, the memory section 528 may expand, warp, or otherwise deform to a lesser extent than the processing tier 524.

The substructure 532 may comprise one or multiple layers or tiers and may be or include, for example, co-packaged optics, a silicon or other semiconductor interposer, one or more PCB layers, one or more bottom-side cooling devices, and/or any other structure and/or devices necessary or useful for using the processing tier 524 and/or the memory sections 528 for their intended purpose.

The system 500 may be one of multiple similar systems 500 that are included in a datacenter such as the datacenter 202. Electrical communication between the system 500, other systems 500, and/or other datacenter components may be accomplished, for example, using co-packaged optics included in the substructure 532, which may be connected to optical, active, and/or high-powered cables and associated connector assemblies; and/or any other electrical communication apparatus or device. Such co-packaged optics may be or comprise, or be configured to receive, one or more pluggable connectors such as an octal small form factor pluggable (OSFP); a Quad Small Form-factor Pluggable (QSFP) connector, or any other connector (e.g., Small Form Pluggable (SFP), C-Form-factor Pluggable (CFP), and the like). The substructure 532 may comprise Ethernet ports, fiber optic connections, Wi-Fi® transceivers, Bluetooth® modules, and/or cellular communication modules, as well as any circuitry necessary to enable the use of such devices for communication with other datacenter components. Additionally, the substructure 532 may be configured to receive, for example, electrical power from an external power source for powering the system 500.

The processing tier 524, the memory sections 528, and the substructure 532 collectively comprise the stack 501 that is cooled by the top-side cold plate 502, which in turn comprises a first portion 504, one or more second portions 508, a stiffener frame 516, intermediate structure 522, and a manifold 523.

The first portion 504 comprises a first material having a first set of thermal properties, including a first CTE. The first material may be, for example, a silicon-based material (or a mixture or alloy of multiple silicon-based materials) with a first CTE that is the same as or similar to the CTE of a silicon die to match a silicon die thermal coefficient of expansion. This can help ensure that the first portion 504 expands, contracts, warps, and/or otherwise deforms to roughly the same extent as the processing tier 524 during use. A plurality of micro-fins 506 extend from the first portion 504 in a direction opposite the processor tier 524.

The micro-fins 506 may be made of the same material as the remainder of the first portion 504 (i.e., the first material), or the micro-fins 506 may be made of a different material. The micro-fins 506 may be manufactured together with the remainder of first portion 504, resulting in a first portion 504 that is a single integral structure, or the micro-fins 506 may be manufactured separately from the remainder of the first portion 504 and subsequently joined to the remainder of the first portion 504 by welding, brazing, chemical bonding, mechanical attachment, or any other joining method. The purpose of the micro-fins 506 is to improve heat dissipation from the first portion 504 (and, in some embodiments, toward the intermediate structure 522, which may comprise, for example, one or more fluid flow paths through which heat transfer fluid flows for the purpose of absorbing heat from the first portion 504, and transferring that heat to a heat sink).

The second portions 508, which in the system 500 are substantially co-planar with the first portion 504, comprise a second material different than the first material and having a second set of thermal properties, including a second CTE different than the first CTE. The second material may be, for example, copper, silver, diamond, graphite, boron nitride, and/or any other thermally conductive material with a second CTE that is larger than the first CTE. A plurality of micro-fins 510 extend from the second portions 508 in a direction opposite the memory sections 528.

The micro-fins 510 may be made of the same material as the remainder of the second portion 508 (i.e., the second material), or the micro-fins 510 may be made of a different material. The micro-fins 510 may be manufactured together with the remainder of the second portions 508 such that the second portions 508 comprise a single integral structure, or the micro-fins 510 may be manufactured separately from the remainder of the second portions 508 and subsequently joined to the remainder of the second portions 508 by welding, brazing, chemical bonding, mechanical attachment, or any other joining method. The purpose of the micro-fins 510 is to improve heat dissipation from the second portions 508 (and, in some embodiments, toward the intermediate structure 522, which may comprise, for example, one or more fluid flow paths through which heat transfer fluid flows for the purpose of absorbing heat from the second portions 508 and the micro-fins 510, and transferring that heat to a heat sink).

Both the first portion 504 and the second portions 508 may be manufactured using any suitable manufacturing process, including but not limited to machining, 3D printing, casting, forging, and sintering.

With the first portion 504 positioned directly on top of the processing tier 524, the first portion 504 will absorb a significant amount of heat from the processing tier 524 during operation thereof, which heat will cause the first portion 504 to expand, warp, and/or otherwise deform (relative to its form when cool). Moreover, the processing tier 524 may expand, warp, and/or otherwise deform as a result of the heat it generates (i.e., before that heat is transferred to the first portion 504, and again relative to its form when cool), which may in turn exert forces on the first portion 504 due to the contact between the processing tier 524 and the first portion 504.

The second portions 508 are positioned directly on top of the memory sections 528, so as to absorb heat generated by the memory sections 528 during operation thereof, which heat will cause the second portions 508 to expand, warp, and/or otherwise deform relative to their form when cool. Moreover, the memory sections 528 may expand, warp, and/or otherwise deform as a result of the heat they generate (i.e., before that heat is transferred to the second portions 508, and against relative to their form when cool). Such expansion, warpage, and/or other deformation may cause the memory sections 528 to exert forces on the second portions 508 due to the contact between the memory sections 528 and the second portions 508.

Because of the differing thermal loads generated by the processing tier 524 and the memory sections 528, as well as the differing thermal properties or characteristics of the first portion 504 and the second portions 508, the expansion, warpage, and/or other deformation of the first portion 504 and of the second portions 508 is unlikely to be identical and may not even be similar. If the first portion and the second portions were to be provided in a single, integral structure (e.g. with the first portion joined directly to the second portion), then these factors would introduce potentially significant stresses into that structure, which could in turn result in thermal interface pump out, voids, cracks, and/or ultimate thermal failure.

To avoid such outcomes and account for the different thermal loads and different sets of thermal properties of the first portion 504 and the second portions 508, as well as the different forces exerted on each, embodiments of the present disclosure include a flexible border or link 512 between the first portion 504 and the second portions 508, which allows the first portion 504 as well as the second portions 508 to expand, contract, warp, and/or otherwise deform independently of each other while remaining connected. The flexible border or link 512 further enables the first portion 504 and the second portions 508 to move relative to each other as a result of any forces exerted thereon by the processing tier 524 and/or the memory sections 528 as a result of the thermal-induced deformation of those components.

The flexible border or link 512 may comprise any elastic material with enough stiffness to hold the first portion 504 and the second portions 508 in substantially the same plane when cool, and with enough elasticity to bend as needed to allow the first portion 504 and the second portions 508 to deform and/or move independently of each other as they expand, contract, warp, and/or otherwise deform, and/or to move as a result of forces applied thereto. The flexible border or link 512 may be made of a different material to offer different stress capabilities a thermal conductor or a thermal isolator. By way of example, the flexible border or link 512 may be or comprise metal (including any metal alloy, such as Nicoloy), rubber, plastic, wood, or another material. A nonmetallic flexible border or link 512 may be provided with a metallized coating to enable the flexible border to be bonded to one or both of the first portion 504 and the second portions 508. Such bonding may utilize brazing, diffusion bonding, or any other technique or process suitable for bonding the flexible border 512 to one or both of the first portion 504 and the second portions 508.

The flexible border or link 512 may be configured with a plurality of folds or bends (e.g., in the style of an accordion or bellows) that allow the flexible border to expand, contract, and/or otherwise bend depending on the direction of a force exerted thereon by the first portion 504 and/or one or both of the second portions 508. A flexible border or link 512 comprising such folds or bends is referred to herein as a flexible bellows linkage. When the stack 501 is in use, for example, and thermal loads generated by the processing tier 524 and the memory sections 528 cause the first portion 504 and the second portions 508 to expand (including horizontally), the first portion 504 will push outward toward the second portions 508 and the second portions 508 will push outward toward the first portion 504. In response to these forces, the flexible bellows linkage that is the flexible border 512 is able to contract. When the thermal loads produced by the processing tier 524 and the memory sections 528 decrease, the opposite will occur: the first portion 504 and the second portions 508 will contract, pulling away from each other and causing the flexible border 512 to expand. Here again, the flexible bellows linkage that is the flexible border 512 enables the expansion of the flexible border 512. The flexible bellows linkage may, in some embodiments, impart stiffness to the flexible border 512, enabling the flexible border 512 to support, at least in part, the first portion 504 in substantially the same plane as the second portions 508.

The cold plate 502 also comprises a stiffener frame 516, which in the system 500 supports an outer side of each of the second portions 508, and therefore indirectly supports the first portion 504 as well. The stiffener frame 516 may be made of stainless steel or any other material with suitable stiffness to maintain its shape while supporting other components of the cold plate (e.g., the second portions 508 and the manifold 523). The stiffener frame 516 may comprise one or more holes passing vertically therethrough for receiving one or more mechanical fasteners that secure the manifold 523 to the stiffener frame 516 (with the intermediate structure 522 consequently secured underneath the manifold 523). In some embodiments, the stiffener frame 516 may also comprise one or more holes passing vertically therethrough for receiving one or more mechanical fasteners that secure the stack 501 (e.g., via the substructure 532) to the stiffener frame 516, and thus to the cold plate 502. In other embodiments, the manifold 523 and/or the stack 501 may be mounted on or to, joined with, and/or otherwise secured to the stiffener frame 516 by, for example, welding, sintering, brazing, diffusion bonding, or chemical bonding.

A flexible link or border 520 secured to both the stiffener frame 516 and the first portions 508 provides support for the first portions 508 (and, indirectly, for the first portion 504). The flexible link or border 520 may, in some embodiments, be the same as or similar to the flexible border 512. The flexible border 520 may be a thermal conductor or a thermal isolator.

More specifically, the flexible link or border 520 may comprise any elastic material with enough stiffness to support all or substantially all of the weight of the second portions 508 (as well as the first portion 504) when the system 500 is in a cool state. The material of the flexible link or border 520 may also have enough elasticity to allow the second portions 508 to expand, contract, warp, and/or otherwise deform, and/or to move as a result of forces applied thereto, without any resulting movement of the stiffener frame 516. By way of example, the flexible link or border 520 may be or comprise metal, rubber, plastic, wood, or another material. A nonmetallic flexible link or border 520 may be provided with a metallized coating to enable the flexible border to be bonded to the second portions 508. Such bonding may utilize brazing, diffusion bonding, or any other technique or process suitable for bonding the flexible link or border 520 to the second portions 508.

The manifold 523 comprises a heat transfer fluid inlet 540 and a heat transfer fluid outlet 542. The heat transfer fluid inlet 540 and the heat transfer fluid outlet 542 may each be in fluid communication with the same external heat transfer fluid reservoir, which may act as a heat sink. Alternatively, the heat transfer fluid inlet 540 may be in fluid communication with a first heat transfer fluid reservoir and the heat transfer fluid outlet 542 may be in fluid communication with a second heat transfer fluid reservoir.

The intermediate structure 522 may comprise or define, in whole or in part, a heat transfer fluid reservoir and/or one or more heat transfer fluid flow paths that receive heat transfer fluid from the heat transfer fluid inlet 540 in the manifold 523, circulate the heat transfer fluid over the first portion 504 and micro-fins 506 as well as over the second portions 508 and the micro-fins 510 to absorb heat emanating therefrom, and discharge the heat transfer fluid via the heat transfer fluid outlet 542 of the manifold 523.

The manifold 523 and/or the intermediate structure 522 of the cold plate 502 may be or comprise any additional cold plate components needed to ensure the proper functioning of the first portion 504, the second portions 508, and the cold plate 502 as a whole.

In some embodiments, the micro-fins 506 and 510 define microchannels through which heat transfer fluid may circulate. In such embodiments, heat transfer fluid may circulate directly over and in between the micro-fins 506 and 510 (e.g., through the microchannels between the micro-fins 506 and between the micro-fins 510), with the manifold 523, the stiffener frame 516, the flexible link 520, the second portion 508, the first portion 504, and the flexible border 512 (together with any needed gaskets, O-rings, seals, or other such components) defining a fluid reservoir through which heat transfer fluid may be circulated.

In other embodiments, the first portion 504 and/or the second portions 508 may comprise one or more microchannels (e.g., passing through the otherwise solid portions thereof) defining a heat transfer fluid flow path through the first portion 504 and the second portion 508. In such embodiments, the cold plate 502 may comprise one or more conduits that channel cooled heat transfer fluid from the intermediate structure 522 to the first portion 504 and/or the second portions 508, and transfer warmed heat transfer fluid from the first portion 504 and/or the second portions 508 to the intermediate structure 522.

Adjacent layers in the system 500 may be bonded or otherwise connected to each other using any method that permits any interoperability required for the system 500 to function as intended.

Other embodiments of the present disclosure may include additional or fewer components than those shown in FIG. 5, and may include different arrangements of one or more of the components described in connection with FIG. 5. For example, a system 500 according to other embodiments of the present disclosure may include additional, re-arranged, or fewer (or no) micro-fins, intermediate structure(s), manifold(s), stiffener frame(s), memory sections, and/or substructure(s).

Although certain types and form factors are used in FIG. 5 and the accompanying written description to represent the various components thereof, the illustrated and described types and form factors are provided by way of example only. The same is true of all other components described herein.

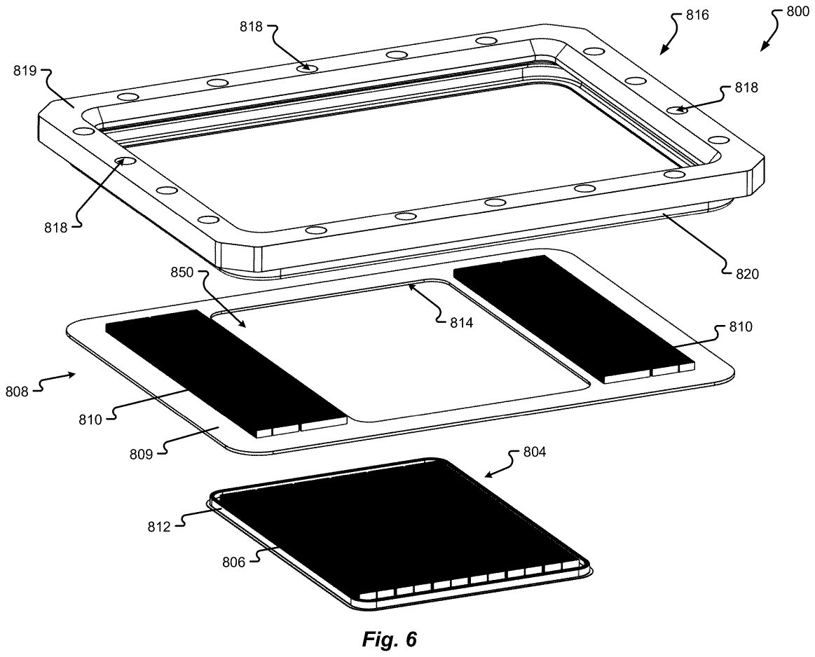

FIGS. 6-11 present various views of a system 800, which forms part of a multi-material cold plate according to embodiments of the present disclosure. The system 800 may be the same as or substantially similar to components of the system 500, as described previously in connection with FIG. 5. In some embodiments, the system 800 serves as the bottom pedestal of a cold plate and is configured to support a manifold (such as the manifold 523 of the system 500) as well as one or more intermediate cold plate structures (such as the intermediate structure 522) secured to the system 800 in between the manifold and the bottom pedestal (i.e., the system 800). The manifold may comprise, for example, one or more heat transfer fluid inlets (such as the heat transfer fluid inlet 540) and one or more heat transfer fluid outlets (such as the heat transfer fluid outlet 542). The intermediate cold plate structure(s) may define (in whole or in part) one or more heat transfer fluid flow paths, which heat transfer fluid enters via the one or more heat transfer fluid inlets on the manifold and exits via the one or more heat transfer fluid outlets on the manifold. In some embodiments, the intermediate cold plate structure(s) may comprise one or more conduits, channels, pipes, tubing, seals, O-rings, gaskets and/or other structure defining, in whole or in part, a fluid flow path to transfer heat transfer fluid to one or more microchannels in one or more components of the system 800. Such microchannels may be defined, for example, by the micro-fins 806 of the first portion 804 and by the micro-fins 810 the second portion 808, or may be separately provided in the base 805 and/or the base 809 of the first portion 804 and the second portion 808, respectively. The intermediate col plate structure(s) may also be configured to receive heated heat transfer fluid from the one or more components of the system 800 and route the heated heat transfer fluid to the manifold and the one or more heat transfer fluid outlets therein.

A multi-material cold plate according to embodiments of the present disclosure may be in fluid communication with one or more heat transfer fluid reservoirs, one or more of which may serve as a heat sink. Heat transfer fluid may be pumped through or otherwise channeled into the one or more heat transfer fluid inlets of the cold plate manifold prior to circulating through the one or more heat transfer fluid flow paths within multi-material cold plate and then exiting the manifold via the one or more heat transfer fluid outlets and returning to a heat transfer fluid reservoir or other heat sink.

Heat transfer fluid, as used herein, refers to any liquid or gas heat transfer fluid, such as water, carbon dioxide, ammonia, hydrocarbons, hydrofluoroolefins, hydrofluorocarbons, hydrofluoroethers, and/or any combination thereof. The heat transfer fluid may be a fluid that will not harm electronic components if the heat transfer fluid leaks from the multi-material cold plate (e.g., from the system 500, the system 800, or any other cold plate component secured to one of those systems), such as deionized water or another dielectric fluid. The heat transfer fluid may be a water solution (e.g. propylene glycol-water), brine, antifreeze, a mixture of antifreeze and water, oil, alcohol, mercury or the like or any other suitable heat conductive fluid. The heat transfer fluid may be an electrically nonconductive cooling liquid, such as deionized water, a coolant such as R-134a, a mixture of water and additives (e.g., a mixture of water and ethylene glycol, or a mixture of water and propylene glycol (e.g., a 25% concentration of propylene glycol in deionized water). The heat transfer fluid may also be a dielectric fluid alone (e.g., not having water for purposes of this disclosure) or a water in combination with an additive including at least one dielectric fluid, such as or one or more of de-ionized water, ethylene glycol, and propylene glycol. In at least one embodiment, the heat transfer fluid may be a mixed solution containing lithium bromide as the absorbent material and water as the carrier material. The heat transfer fluid may also be a two-phase coolant that has a boiling point that is below the expected operating temperature of the electronic devices. Exemplary two-phase coolants include 2, 3, 3, 3-tetrafluoropropene, 1, 1, 1, 2-tetrafluoroethane and water.

The system 800 comprises a first portion 804 (which may be the same as or similar to the first portion 504 of the system 500), a second portion 808 (which may be the same as or similar to the second portions 508 of the system 500), and a stiffener frame 816 (which may be the same as or similar to the stiffener frame 516 of the system 500).

The first portion 804 is a micro-finned structure comprising a base 805 and a plurality of micro-fins 806. The first portion 804 is made of a first material having a first set of thermal properties (e.g., thermal conductivity, specific heat capacity, melting temperature), including a first CTE. The first material may be, for example, silicon or a silicon-based material, and may be engineered or selected to have a CTE that is the same as or similar to the CTE of a silicon die, so that the silicon die and the first portion 804 exhibit similar behavior when subjected to similar thermal loads. The micro-fins 806 are configured to facilitate the dissipation of heat absorbed by the first portion 804 through the base 805. The micro-fins 806 may be arranged in rows and/or columns. The micro-fins 806 may be machined, etched, or otherwise created directly into or from the base 805, such that the first portion 804 comprises a single, integral piece of the same material. Alternatively, the micro-fins 806 may be manufactured separately from the base 805, whether from the same material or (in other embodiments) from a different material, and subsequently mounted on, joined to, or otherwise secured to the base 805 in any manner that preserves thermal conductivity from the base 805 to the micro-fins 806, so as to form the first portion 804.

The second portion 808 is also a micro-finned structure comprising a base 809 and a plurality of micro-fins 810. The second portion 808 is made of a second material having a second set of thermal properties, including a second CTE, different from the first set of thermal properties and the first CTE. The second material may be a highly-conductive material such as copper, silver, diamond, graphite, boron nitride, and/or any other thermally conductive material, and may be engineered or selected to have a high CTE, and/or a higher CTE than the first CTE. The micro-fins 810 are configured to facilitate the dissipation of heat absorbed by the second portion 808 through the base 809. The micro-fins 810 may be arranged in rows and/or columns. The micro-fins 810 may be machined, etched, or otherwise created directly into or from the base 809, such that the second portion 808 comprises a single, integral piece of the same material. Alternatively, the micro-fins 810 may be manufactured separately from the base 809, whether from the same material or (in other embodiments) from a different material, and subsequently mounted on, joined to, or otherwise secured to the base 809 in any manner that preserves thermal conductivity from the base 809 to the micro-fins 810, so as to form the second portion 808.

Both the first portion 804 and the second portion 808 may be manufactured using any suitable manufacturing process or combination thereof, including but not limited to machining, 3D printing, forging, and sintering.

The second portion 808 comprises a central cutout 850 with a perimeter 814 that is longer than a perimeter of the first portion 804. As a result, when the first portion 804 is arranged in the same horizontal plane as the second portion 808, the first portion 804 fits inside the cutout 850 without touching any portion of the perimeter 814.

A flexible border 812, also referred to herein as a flexible link or linkage 812, fills the space between the first portion 804 to the second portion 808 and joins those two components (and, more specifically, joins the base 805 to the base 808). The flexible border 812 may be the same as or similar to the flexible border 512 of the system 500. The purpose of the flexible border 812 is to support the first portion 804 so that, in a cooled state, the first portion 804 is substantially co-planar with the second portion 808, while also enabling the first portion 804 to expand, contract, warp, or otherwise deform (and also to move up or down, left or right, and/or front or back) independently of the second portion 808, and vice versa. Using a flexible border 812 between the first portion 804 and the second portion 808 enables the use of different materials with different thermal properties or characteristics for the first portion 804 and the second portion 808. If the first portion 804 were instead placed in direct contact with the second portion 808, the two materials would respond differently to the thermal loads placed thereon, introducing stresses that could cause voids, cracks, thermal interface pump out, and ultimately thermal failure.

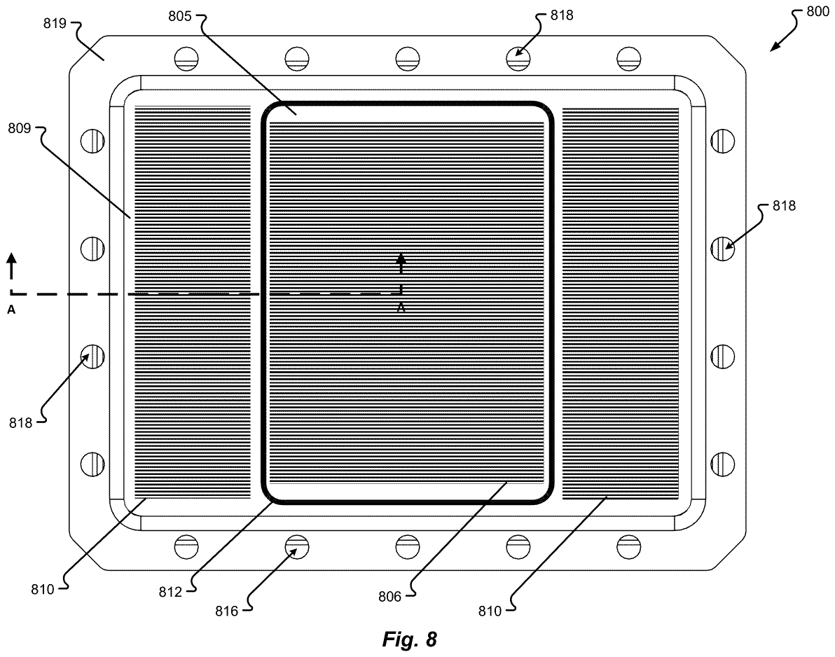

FIG. 8 illustrates an assembled isometric top view of all three sections. The XY expansion and contraction in each section can differ as a result of the different heat flux of the silicon below, but the flexible link 812 allows these changes in size to not impact each other.

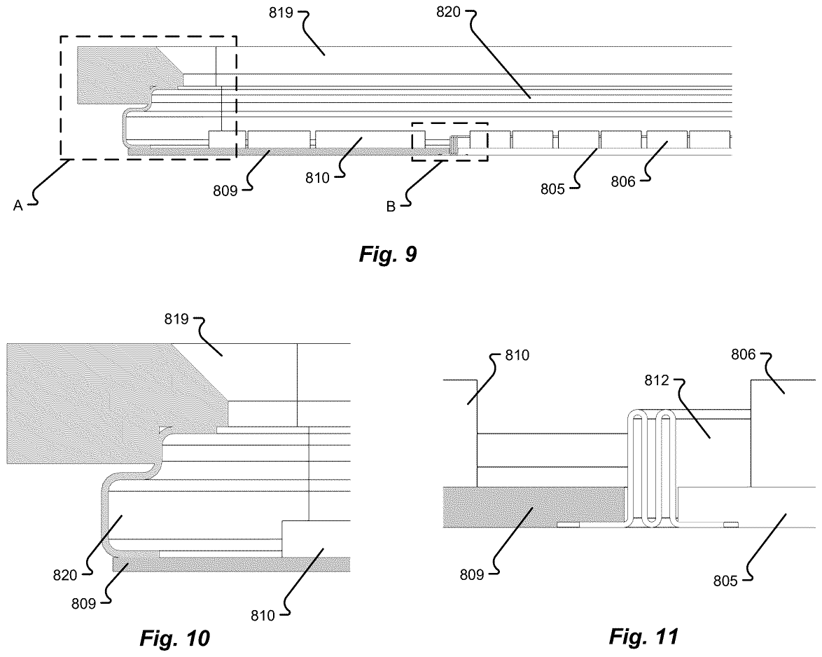

As especially visible in the views of FIGS. 9-11, the flexible link 812 of the system 800 extends from underneath the base 805 to underneath the base 809, and has multiple folds or bends therein (e.g. in the style of an accordion or a bellows) such that the flexible link 812 passes multiple times through the space between the base 805 and the base 809. A flexible border or link 812 comprising folds or bends is referred to herein as a flexible bellows linkage. When the system 800 is in use, for example, and thermal loads generated by a silicon package (such as the stack 501) directly underneath the system 800 cause the first portion 804 and the second portion 808 to expand, contract, warp, or otherwise deform, and/or move forward, backward, left, right, up, or down, the flexible bellows linkage can expand, contract, or deform as necessary to accommodate the independent deformation and/or movement of the first portion 804 and the second portion 808 while still maintaining the connection therebetween. In other embodiments, other types of flexible borders may be used, including flexible borders without any bends and/or flexible borders that are configured to stretch and contract rather than bend to accommodate deformation and/or movement of the first portion 804 and/or of the second portion 808.

The flexible link 812 may comprise any elastic material with enough stiffness to hold the first portion 804 and the second portion 808 in substantially the same plane when cool, and with enough elasticity to allow the first portion 804 and the second portion 808 to expand, contract, warp, and/or otherwise deform, and/or to move as a result of forces applied thereto, independently of each other, while still remaining joined. The flexible link 812 may be a thermal conductor or a thermal isolator. By way of example, the flexible border or link 812 may be or comprise metal (including any metal alloy, such as Nicoloy), rubber, plastic, wood, or another material. When the flexible border or link 812 is not metallic, some or all of the flexible border or link 812 may be provided with a metallized coating to enable the flexible border to be bonded to one or both of the base 805 of the first portion 804 and the base 809 of the second portion 808. Such bonding may utilize brazing, diffusion bonding, or any other technique or process suitable for bonding the flexible border 812 to one or both of the first portion 804 and the second portion 808.

The stiffener frame 816 comprises stiffening member 819 and a flexible link 820 that together provide support for the second portion 808 (and, indirectly, for the first portion 804). The flexible link 820 is secured to a lower surface of the stiffening member 819, as well as to an outer edge or perimeter of the base 809 of the second portion 808. The flexible link 820 may be the same as or substantially similar to the flexible link 812, including in terms of material and elasticity. The flexible link 820 may be a thermal conductor or a thermal isolator. The flexible link 820 is also a flexible bellows linkage with one or more bends that enable the flexible link 820 to expand or contract to accommodate expansion, contract, deformation, and/or movement of the second portion 808 in response to thermal loads and/or other forces exerted thereon by a silicon package (e.g., a stack 501) directly underneath or otherwise in contact with the system 800, while still maintaining a connection between the stiffening member 819 and the second portion 808. In other embodiments, other types of flexible links may be used, including flexible links without any bends and/or flexible borders that are configured to stretch and contract rather than bend to accommodate deformation and/or movement of the second portion 808 relative to the stiffener frame 816.

The flexible link 820 may be bonded to the stiffening member 819 and/or to the second portion 808, using brazing, diffusion bonding, or any other technique or process suitable therefor, and may be provided with a metallized coating over some or all of the surface of the flexible link 820 to facilitate such bonding.

The second portion 808 surrounds the first portion 804, and the stiffener frame 816 surrounds the second portion 808. The stiffener frame 816 may be made of stainless steel or any other material with a strength and stiffness sufficient to support the second portion 808 (and, therefore, the first portion 804) as well as any additional structure secured thereto (e.g., intermediate cold plate structure, a cold plate manifold, etc.). The stiffening member 819 and the flexible link 820 may be manufactured as a single integral piece, or the two components may be manufactured separately and subsequently joined together. The stiffening member 819 may be the same material as the flexible link 820, or the two components may be made of different materials. In some embodiments, the stiffener frame 816 may also support, in whole or in part, a silicon package (such as the stack 501) mounted directly underneath the first portion 804 and the second portion 808. The stiffening member 819 is provided with a plurality of through-holes 818, which may be configured to receive one or more mechanical fasteners for securing a cold plate manifold thereto, and/or for securing a silicon package (such as the stack 501) thereto.

In use, a cold plate manifold and any additional cold plate intermediate structure are mounted to the top of the system 800, and resulting structure is mounted on, secured adjacent to, or otherwise positioned in thermal communication with a silicon package comprising, for example, a first part with one or more processor cores (which may be the same as or similar to the processing tier 524 of the stack 501, for example) and a second part with one or more memory layers (which may be the same as or similar to the memory sections 528 of the stack 501, for example). The one or more processor cores may comprise one or more GPUs, one or more CPUs, and/or one or more of any other processor core or processing unit described herein. The one or more memory layers may comprise one or more memory devices, such as a DRAM and/or an HBM silicon area. The one or more memory layers may additionally or alternatively comprise any other memory device, including any memory device described herein. In some examples, the first portion may be mounted to a part of the silicon package utilizing a first power level while the second portion may be mounted to a part of the silicon package utilizing a second power level. The first part of the silicon package may operate at a first power level, and the second part of the silicon package may operate at a second power level different than the first power level. As a result, the first part of the silicon package may generate a thermal load different than (e.g., higher than) the thermal load generated by the second part of the silicon package.

When a multi-material cold plate comprising the system 800 is mounted on, secured adjacent to, or otherwise positioned in thermal communication with the silicon package, the multi-finned structure that is the first portion 804 is positioned directly on top of or otherwise in contact with the first part of the silicon package, and the multi-finned structure that is the second portion 808 is positioned directly on top of or otherwise in contact with the second part of the silicon package. As heat is transferred from the first part of the silicon package to the first portion 804, and from the second part of the silicon package to the second portion 808, the first portion 804 and the second portion 808 can expand, warp, and/or otherwise deform, and move, independently of each other, thus helping to ensure that the structural integrity as well as the functionality of the system 800 (and the entire cold plate of which the system 800 is a part) is maintained.

Persons of ordinary skill in the art will appreciate that the second portion 808 as described herein could be configured to be placed directly on top of the one or more processor cores, and the first portion 804 could be configured to be placed directly on top of the one or more memory layers. In such embodiments, the second portion 808 comprises a material with a CTE and other thermal properties described above in connection with the first portion 804, and the first portion 804 comprises a material with a CTE and other thermal properties described above in connection with the second portion 808.

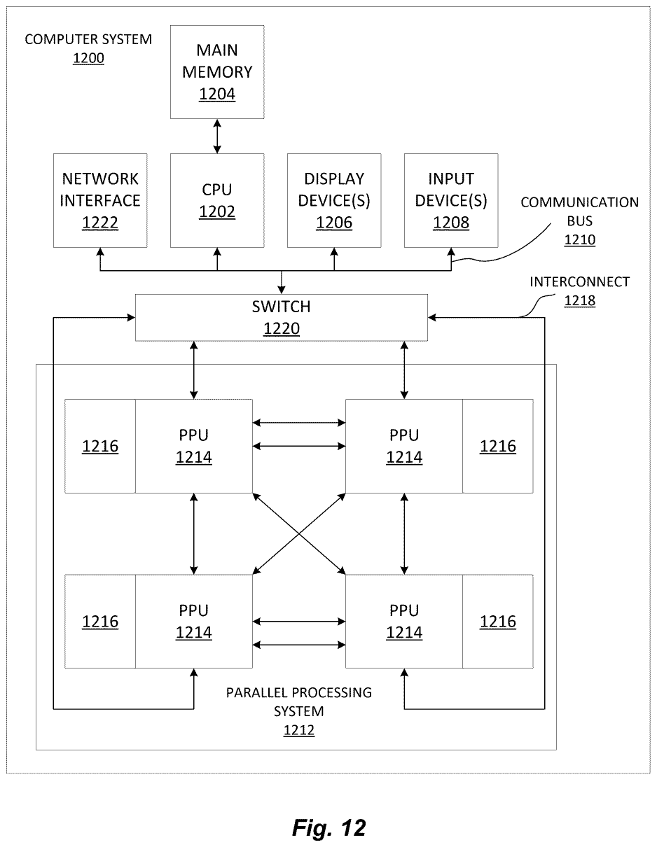

FIG. 12 illustrates a computer system 1200, according to at least one embodiment. In at least one embodiment, computer system 1200 is configured to implement various processes and methods described throughout this disclosure.

In at least one embodiment, computer system 1200 comprises, without limitation, at least one central processing unit (“CPU”) 1202 that is connected to a communication bus 1210 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 1200 includes, without limitation, a main memory 1204 and control logic (e.g., implemented as hardware, software, or a combination thereof) and data are stored in main memory 1204 which may take form of random access memory (“RAM”). In at least one embodiment, a network interface subsystem (“network interface”) 1222 provides an interface to other computing devices and networks for receiving data from and transmitting data to other systems from computer system 1200.

In at least one embodiment, computer system 1200, includes, without limitation, input devices 1208, parallel processing system 1212, and display devices 1206 which can be implemented using a conventional cathode ray tube (“CRT”), liquid crystal display (“LCD”), light emitting diode (“LED”), plasma display, or other suitable display technologies. In at least one embodiment, user input is received from input devices 1208 such as keyboard, mouse, touchpad, microphone, and more. In at least one embodiment, each of the foregoing modules can be situated on a single semiconductor platform to form a processing system.

In at least one embodiment, computer programs in the form of machine-readable executable code or computer control logic algorithms are stored in main memory 1204 and/or secondary storage. Computer programs, if executed by one or more processors, enable system 1200 to perform various functions in accordance with at least one embodiment. Memory 1204, secondary storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, the architecture and/or functionality of various is/are implemented in the context of CPU 1202; parallel processing system 1212; an integrated circuit capable of at least a portion of capabilities of both CPU 1202 and parallel processing system 1212; a chipset (e.g., a group of integrated circuits designed to work and sold as a unit for performing related functions, etc.); and any suitable combination of integrated circuit(s).

In at least one embodiment, the architecture and/or functionality of various figures described herein is/are implemented in the context of a general computer system, a circuit board system, a game console system dedicated for entertainment purposes, an application-specific system, and more. In at least one embodiment, computer system 1200 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 1212 includes, without limitation, a plurality of parallel processing units (“PPUs”) 1216 and associated memories 1216. In at least one embodiment, PPUs 1216 are connected to a host processor or other peripheral devices via an interconnect 1218 and a switch 1220 or multiplexer. In at least one embodiment, parallel processing system 1212 distributes computational tasks across PPUs 1216 which can be parallelizable—for example, as part of a distribution of computational tasks across multiple graphics processing unit (“GPU”) thread blocks. In at least one embodiment, memory is shared and accessible (e.g., for read and/or write access) across some or all of PPUs 1216, although such shared memory may incur performance penalties relative to the use of local memory and registers resident to a PPU 1216. In at least one embodiment, operation of PPUs 1216 is synchronized through use of a command such as syncthreads( ), which requires all threads in a block (e.g., executed across multiple PPUs 1216) to reach a certain point of execution of code before proceeding.

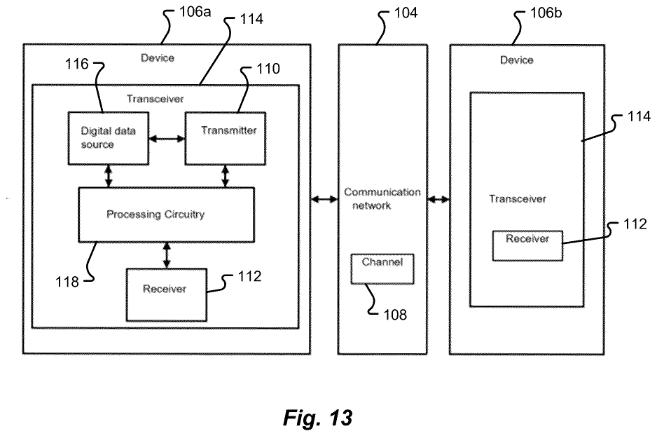

As shown in FIG. 13, in one specific but non-limiting example, the communication network 104 is a network that enables data transmission between the devices 106a and 106b using data signals (e.g., digital, optical, wireless signals).

Each type of network offers specific advantages tailored to different operational requirements. For instance, an IP network or Ethernet network may provide widespread compatibility and ease of integration, supporting various protocols and applications across the datacenter 102 and the network device(s) 106 (and/or external devices). An InfiniBand network may offer high throughput and low latency, ideal for HPC environments where rapid data transfer and minimal delay are required. Fibre Channel networks may be employed for their robust performance in storage area networks (SANs), ensuring fast and reliable access to storage resources. Cellular and wireless communication networks may be used to extend connectivity to remote or mobile devices for increased flexibility and accessibility.

As noted above, the network devices 106a, 106b may include one or more of Personal Computer (PC), a laptop, a tablet, a smartphone, a server, a collection of servers, and/or any suitable computing device for sending and receiving signals over the communication network 104. In at least one example embodiment, the one or more network devices 106 correspond to another datacenter, similar to or the same as datacenter 102.

Each network device 106 may be provided with transmitter functionality 110, receiver functionality 112, and/or transceiver functionality 114. The transmitter functionality 110, receiver functionality 112, and/or transceiver functionality 114 may include hardware and/or software to support the sending and/or receiving of data across the communication network 104, through one or more communication channels 108, for example.

A network device 106 may also include a digital data source 116 and/or processing circuitry 118 to support interactions within the transceiver 114 or to support interactions between components of the transceiver 114 and other components of the device 106. For instance, the processing circuitry 118 may be included in the transceiver 114 as illustrated or may be external to the transceiver 114, without departing from the scope of the present disclosure.

Optical Datacenter Networks rely on allocation and deallocation of light paths from the data sources to the destinations end-ports to guarantee no light collisions and data loss occur in the fabric. Traditionally the allocation algorithms are run from a central entity which considers the entire demand for source and destination flows and try to find the most dense mapping of these demands to network resources over a single or multiple time periods.

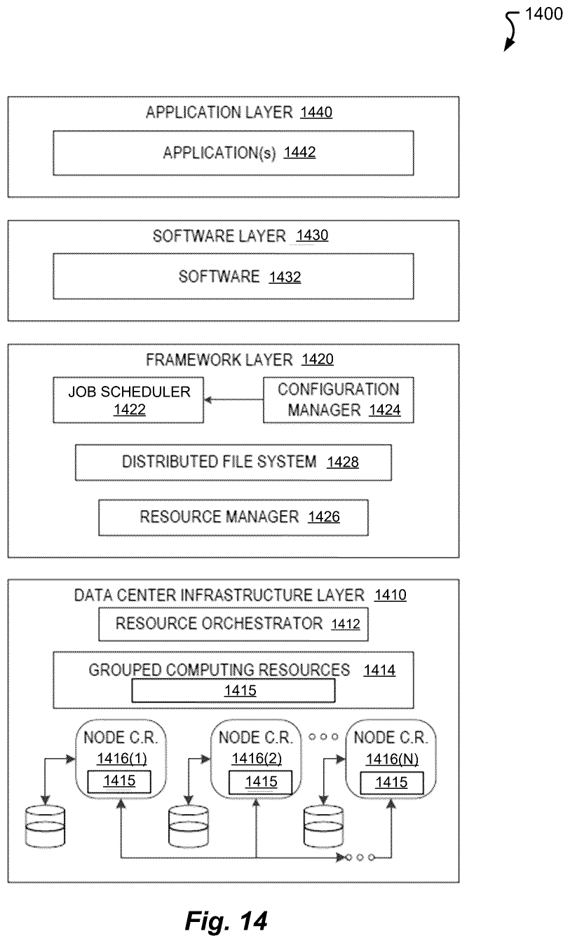

FIG. 14 illustrates additional components of an example datacenter 1400 according to at least some embodiments of the present disclosure. The datacenter 1400 may also include one or more modules subject to one or more cooling/thermal management features as described herein.

In at least one embodiment, datacenter 1400 includes a datacenter infrastructure layer 1410, a framework layer 1420, a software layer 1430, and an application layer 1440. In at least one embodiment, the infrastructure layer 1410, the framework layer 1420, the software layer 1430, and the application layer 1440 may be partly or fully provided via computing components on server trays located in racks of the datacenter 1400 (or of another datacenter, such as the datacenter 102). This enables cooling systems of the present disclosure to direct cooling to certain ones of the computing features and the interconnect features, in an efficient and effective manner. Further, aspects of the datacenter 1400, including the datacenter infrastructure layer 1410, the framework layer 1420, the software layer 1430, and the application layer 1440 may be used to support selection or design of the intermediate layers. As such, the discussion in reference to FIG. 14 may be understood to apply to the hardware and software features required to enable or support cooling functionality, for instance.

In at least one embodiment, as in FIG. 14, datacenter infrastructure layer 1410 may include a resource orchestrator 1412, grouped computing resources 1414, and node computing resources (“node C.R.s”) 1416(1)-1416(N), where “N” represents any whole, positive integer. In at least one embodiment, node C.R.s 1416(1)-1416(N) may include, but are not limited to, any number of central processing units (“CPUs”) or other processors (including accelerators, field programmable gate arrays (FPGAs), graphics processors, etc.), memory devices (such as dynamic read-only memory), storage devices (such as solid state or disk drives), network input/output (“NW I/O”) devices, network switches, virtual machines (“VMs”), power modules, and cooling modules, etc. In at least one embodiment, one or more node C.R.s from among node C.R.s 1416(1)-1416(N) may be a server having one or more of above-mentioned computing resources.

In at least one embodiment, grouped computing resources 1414 may include separate groupings of node C.R.s housed within one or more racks (not shown), or many racks housed in datacenters at various geographical locations (also not shown). Separate groupings of node C.R.s within grouped computing resources 1414 may include grouped compute, network, memory or storage resources that may be configured or allocated to support one or more workloads. In at least one embodiment, several node C.R.s including CPUs or processors may be grouped within one or more racks to provide compute resources to support one or more workloads. In at least one embodiment, one or more racks may also include any number of power modules, cooling modules, and network switches, in any combination.

In at least one embodiment, resource orchestrator 1412 may configure or otherwise control one or more node C.R.s 1416(1)-1416(N) and/or grouped computing resources 1414. In at least one embodiment, resource orchestrator 1412 may include a software design infrastructure (“SDI”) management entity for datacenter 1400. In at least one embodiment, resource orchestrator may include hardware, software or some combination thereof.

In at least one embodiment, as shown in FIG. 14, framework layer 1420 includes a job scheduler 1422, a configuration manager 1424, a resource manager 1426 and a distributed file system 1428. In at least one embodiment, framework layer 1420 may include a framework to support software 1432 of software layer 1430 and/or one or more application(s) 1442 of application layer 1440. In at least one embodiment, software 1432 or application(s) 1442 may respectively include web-based service software or applications, such as those provided by Amazon Web Services, Google Cloud and Microsoft Azure. In at least one embodiment, framework layer 1420 may be, but is not limited to, a type of free and open-source software web application framework such as Apache Spark™ (hereinafter “Spark”) that may utilize distributed file system 1428 for large-scale data processing (such as “big data”). In at least one embodiment, job scheduler 1422 may include a Spark driver to facilitate scheduling of workloads supported by various layers of datacenter 1400. In at least one embodiment, configuration manager 1424 may be capable of configuring different layers such as software layer 1430 and framework layer 1420 including Spark and distributed file system 1428 for supporting large-scale data processing. In at least one embodiment, resource manager 1426 may be capable of managing clustered or grouped computing resources mapped to or allocated for support of distributed file system 1428 and job scheduler 1422. In at least one embodiment, clustered or grouped computing resources may include grouped computing resource 1414 at datacenter infrastructure layer 1410. In at least one embodiment, resource manager 1426 may coordinate with resource orchestrator 1412 to manage these mapped or allocated computing resources.

In at least one embodiment, software 1432 included in software layer 1430 may include software used by at least portions of node C.R.s 1416(1)-1416(N), grouped computing resources 1414, and/or distributed file system 1428 of framework layer 1420. One or more types of software may include, but are not limited to, Internet web page search software, e-mail virus scan software, database software, and streaming video content software.

In at least one embodiment, application(s) 1442 included in application layer 1440 may include one or more types of applications used by at least portions of node C.R.s 1416(1)-1416(N), grouped computing resources 1414, and/or distributed file system 1428 of framework layer 1420. One or more types of applications may include, but are not limited to, any number of a genomics application, a cognitive compute, and a machine learning application, including training or inferencing software, machine learning framework software (such as PyTorch, TensorFlow, Caffe, etc.) or other machine learning applications used in conjunction with one or more embodiments.

In at least one embodiment, any of configuration manager 1424, resource manager 1426, and resource orchestrator 1412 may implement any number and type of self-modifying actions based on any amount and type of data acquired in any technically feasible fashion. In at least one embodiment, self-modifying actions may relieve a datacenter operator of datacenter 1400 from making possibly bad configuration decisions and possibly avoiding underutilized and/or poor performing portions of a datacenter.

In at least one embodiment, datacenter 1400 may include tools, services, software or other resources to train one or more machine learning models or predict or infer information using one or more machine learning models according to one or more embodiments described herein. In at least one embodiment, a machine learning model may be trained by calculating weight parameters according to a neural network architecture using software and computing resources described above with respect to datacenter 1400. In at least one embodiment, trained machine learning models corresponding to one or more neural networks may be used to infer or predict information using resources described above with respect to datacenter 1400 by using weight parameters calculated through one or more training techniques. Deep learning may be advanced using any appropriate learning network and the computing capabilities of the datacenter 1400. As such, a deep neural network (DNN), a recurrent neural network (RNN) or a convolutional neural network (CNN) may be supported either simultaneously or concurrently using the hardware in the datacenter. Once a network is trained and successfully evaluated to recognize data within a subset or a slice, for instance, the trained network can provide similar representative data for using with the collected data.

In at least one embodiment, datacenter 1400 may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or perform inferencing of information, such as pressure, flow rates, temperature, and location information, or as any other artificial intelligence service.

Inference and/or training logic 1415 may be used to perform inferencing and/or training operations associated with one or more embodiments. In at least one embodiment, inference and/or training logic 1415 may be used in a datacenter 1400 (whether in grouped computing resources 1414, in one or more node C.R.s 1416(1)-1416(N), or elsewhere) or in other systems described herein, for inferencing or predicting operations based, at least in part, on weight parameters calculated using neural network training operations, neural network functions and/or architectures, or neural network use cases described herein. In at least one embodiment, inference and/or training logic 1415 may include, without limitation, hardware logic in which computational resources are dedicated or otherwise exclusively used in conjunction with weight values or other information corresponding to one or more layers of neurons within a neural network. In at least one embodiment, inference and/or training logic 1415 may be used in conjunction with an application-specific integrated circuit (ASIC), such as a Tensorflow® Processing Unit from Google, an inference processing unit (IPU) from Graphcore™, or a Nervana® (such as “Lake Crest”) processor from Intel Corp.

In at least one embodiment, inference and/or training logic 1415 may be used in conjunction with central processing unit (CPU) hardware, graphics processing unit (GPU) hardware or other hardware, such as field programmable gate arrays (FPGAs). In at least one embodiment, inference and/or training logic 1415 includes, without limitation, code and/or data storage modules which may be used to store code (such as graph code), weight values and/or other information, including bias values, gradient information, momentum values, and/or other parameter or hyperparameter information. In at least one embodiment, each of the code and/or data storage modules is associated with a dedicated computational resource. In at least one embodiment, the dedicated computational resource includes computational hardware that further include one or more ALUs that perform mathematical functions, such as linear algebraic functions, only on information stored in code and/or data storage modules, and results from which are stored in an activation storage module of the inference and/or training logic 1415.

The switches within each layer (e.g., edge layer, aggregation layer, core layer) may be 1U switches. The switches may be electrical switches, optical switches, hybrid electro-optical switches, or any combination thereof. The switches may be implemented with suitable hardware and/or software that enables the routing of signals in the appropriate domain. For example, an electrical switch may include receivers that receive and convert optical signals into electrical signals for routing within the electrical switch. A receiver of an electrical switch may include a transimpedance amplifier (TIA), a photodetector, and a controller which all serve to convert the optical signals into electrical signals. Each electrical switch may further include transmitters that convert electrical signals routed within the electrical switch into optical signals for output to another switch (optical or electrical) within the system. For example, a transmitter of an electrical switch may include a light source, a modulator, and a controller that controls the modulator and light source. In some embodiments, receiver/transmitter pairs may be integrated into a single transceiver. Each electrical switch may also include internal switching circuitry for routing electrical signals within the electrical switch.

A switch, whether electric, optoelectronic, and/or quantum, may include input circuit(s) and output circuit(s), linked by switching core. In some embodiments, a switch may include multiple inputs and outputs.

A number of architectures of this type have been proposed, including “Next Generation I/O” (NGIO) and “Future I/O” (FIO), culminating in the “InfiniBand” architecture, which has been advanced by a consortium led by a group of industry leaders (including Intel, Sun, Hewlett Packard, IBM, Compaq, Dell and Microsoft). Storage Area Networks (SAN) provide a similar, packetized, serial approach to high-speed storage access, which can also be implemented using an InfiniBand fabric.

Communications between a parallel bus and a packet network generally require a communications interface, to convert bus cycles into appropriate packets and vice versa. For example, a host channel adapter or target channel adapter can be used to link a parallel bus, such as the PCI bus, to the InfiniBand fabric. When the adapter receives data from a device on the PCI bus, it inserts the data in the payload of an InfiniBand packet, and then adds an appropriate header and error checking code, such as a cyclic redundancy check (CRC) code, as required for network transmission. The InfiniBand packet header includes a routing header and a transport header. The routing header contains information at the data link protocol level, including fields required for routing the packet within and between fabric subnets. The transport header contains higher-level, end-to-end transport protocol information. Similar headers are used in other types of packet networks known in the art, such as Internet Protocol (IP) networks.

Embodiments of the present disclosure may comprise any suitable material known in the art (e.g., carbon steel, aluminum, polymers, ceramics, and the like), particularly materials possessing high thermal conductivity. By way of example, cage receptacle assemblies as described herein may be created by an extrusion and/or machine process. In such an example, a single body of fixed cross-sectional area may be produced by an extrusion process. This single body may be created via pushing a base material (e.g., a polymer) through a dimensioned die such that the cage body 401 of the cage receptacle assembly is created. In some embodiments, the single body may be created as two separate elements (e.g., a top cage member and bottom cage member) where the two separate elements are further attached to form the single body. This extruded body may then be modified through a machine process whereby material is removed from the extruded body to create the finished cage receptacle assembly 400. The machining process may include any or all of micro machining, turning, milling, drilling, grinding, water jet cutting, EDM, AFM, USM, CNC, and the like, in any order or combination. Although described as an extrusion and machine process of a single piece of material, any portion or sub-portion of the cage receptacle assembly may be separately formed or attached without departing from the scope of this disclosure.

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components (e.g., components of printed circuit boards, transceivers, cables, etc.) may be used in conjunction with the cage receptacle assembly. Therefore, it is to be understood that the disclosures are not to be limited to the specific embodiments disclosed and that modifications and other embodiments are intended to be included within the scope of the appended claims.

It is to be appreciated that any feature described herein can be claimed in combination with any other feature(s) as described herein, regardless of whether the features come from the same described embodiment.

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

What is claimed is:

1. A system, comprising:
a silicon package; and
a cold plate in thermal contact with the silicon package, wherein the cold plate comprises a first portion formed of a first material and a second portion formed of a second material, wherein the first material comprises a first set of thermal properties and the second material comprises a second set of thermal properties different than the first set.

2. The system of claim 1, wherein the first portion is substantially co-planar with the second portion.

3. The system of claim 1, wherein the first portion is joined to the second portion by a flexible border.

4. The system of claim 3, wherein the flexible border is bonded to at least one of the first portion or the second portion.

5. The system of claim 3, wherein the flexible border is bonded to both the first portion and the second portion.

6. The system of claim 3, wherein the flexible border comprises a flexible bellows linkage.

7. The system of claim 1, wherein at least one of the first portion and the second portion comprises microchannels.

8. The system of claim 1, wherein the first portion comprises a micro-finned structure.

9. The system of claim 8, wherein the silicon package comprises a GPU core, and the micro-finned structure is positioned directly on top of the GPU core.

10. The system of claim 8, wherein the silicon package comprises a GPU core, and the micro-finned structure is positioned in contact with the GPU core.

11. The system of claim 1, wherein the second portion comprises a micro-finned structure.

12. The system of claim 11, further comprising:
a memory device;
wherein the micro-finned structure is directly on top of the memory device.

13. The system of claim 12, wherein the memory device is a low-power memory device.

14. The system of claim 13, wherein the memory device comprises a DRAM or HBM silicon area.

15. The system of claim 1, wherein the first portion comprises a silicon-based material.

16. The system of claim 1, wherein the first portion has a coefficient of thermal expansion substantially similar to a silicon die thermal coefficient of expansion.

17. The system of claim 1, wherein the second portion comprises a conductive material.

18. The system of claim 17, wherein the conductive material is copper.

19. The system of claim 1, further comprising a stiffener frame.

20. The system of claim 19, wherein the stiffener frame surrounds both the first portion and the second portion of the cold plate.

21. The system of claim 19, wherein the stiffener frame comprises a flexible bellows linkage connected to at least one of the first portion and the second portion.

22. A system comprising:
a silicon package comprising a processor core; and
a cold plate in thermal communication with the silicon package, the cold plate comprising:
a first portion having a first coefficient of thermal expansion;
a second portion having a second coefficient of thermal expansion different than the first coefficient of thermal expansion; and
a stiffener frame configured to provide support to both the first portion and the second portion.

23. The system of claim 22, further comprising a flexible border between the first portion and the second portion.

24. The system of claim 23, wherein the flexible border allows each of the first portion and the second portion to expand and contract independently of each other.

25. The system of claim 23, wherein the flexible border is bonded to at least one of the first portion and the second portion using a brazing or a bonding diffusion technique.

26. The system of claim 22, wherein a first part of the silicon package is mounted to the first portion and a second part of the silicon package is mounted to the second portion.

27. The system of claim 26, wherein the first part uses a first power level and the second part uses a second power level.

28. The system of claim 27, wherein the first part comprises a memory device and the second part comprises the processor core.

29. A system comprising:
a manifold defining a heat transfer fluid inlet and a heat transfer fluid outlet; and
a pedestal, comprising:
a first portion having a first set of thermal characteristics;
a second portion having a second set of thermal characteristics different than the first set of thermal characteristics, the second portion connected to the first portion via a flexible link; and
a stiffener frame configured to provide support to at least one of the first portion and the second portion;
wherein the manifold is removably secured to the pedestal via the stiffener frame.

30. The system of claim 29, wherein the first portion is in thermal contact with at least one processor core, and the second portion is in thermal contact with at least one memory device.

31. The system of claim 29, wherein the second portion surrounds the first portion, the stiffener frame surrounds the second portion, and the stiffener frame comprises a second flexible link connected to the second portion.
